(19) United States
(12) Patent Application Publication
(10) Pub. No.: US 2007/0151753 A1
(43) Pub. Date: Jul. 5, 2007

(54) Printed circuit board having plated through hole with multiple connections and method of fabricating same

(76) Inventors: Soo Fung Thor, Georgetown (MY); Amir Nur Rashid Wagiman, Sungai Petani (MY); Chee Kheong Yoon, Penang (MY)

Correspondence Address: INTEL CORPORATION;c/o INTELLEVATE, LLC, P.O. BOX 52050, MINNEAPOLIS, MN, 55402, US

(21) Appl. No.: 11/323,366

(22) Filed: Dec. 29, 2005

(51) Int. Cl. H05K 1/00; H05K 3/00

(52) U.S. Cl. 174/258; 174/262; 361/748; 29/829; 29/846

(57) ABSTRACT

A method of fabricating a printed circuit board, a printed circuit board formed according to the method, and a system including the printed circuit board. The method comprises: providing a substrate; providing a through hole opening in the substrate; metallizing walls of the opening to provide a conductive coating thereon defining a hollow region within the opening; providing gaps in the conductive coating to yield a corresponding number of conductive coating portions separated by the gaps and by the hollow region; filling the gaps and the hollow region with an electrically insulating material to electrically isolate the conductive coating portions from one another to provide a plated through hole including a plurality of connections; wherein each of the conductive coating portions defines at least part of a connection of the plurality of connections; and circuitizing the substrate to provide conductive traces thereon connected to corresponding ones of the plurality of connections to yield the printed circuit board.

### FIELD

Embodiments of the present invention relate to the provision of interconnects on microelectronic wafers.

### BACKGROUND

In recent years, printed circuit board (PCB) technology has placed greater emphasis on a closer spacing of circuit elements on the board. It is typically now necessary to make a large number of plated through hole (PTH) connections from one side of the board to the other. In order to provide the PTH's, current practice metallizes holes drilled in a core layer typically by electrolessly plating the inside of the holes with a conductive material such as copper. The above provides a through connection from one side of the core layer to the other. In addition, to accommodate the need for closer spacing of circuit elements, the prior art typically provides PTH's having reduced diameters, such as, for example, diameters up to about 250 microns, and/or a reduced pitch, such as, for example, a pitch of up to about 475 microns, to provide an increased number of connections.

However, disadvantageously, providing PTH's with reduced diameters and a reduced pitch has proven to present multiple challenges to the drilling process typically used to provide the holes of the PTH's. As a result, providing PTH's having reduced diameters and a reduced pitch has proven to be a costly process for addressing the need for an increased number of connections on a PCB.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1a shows a top plan view of a substrate for a printed circuit board;

FIG. 1b is a longitudinal cross sectional view of the substrate of FIG. 1a along lines A-A.

FIG. 2a is a view similar to FIG. 1a showing the substrate as having been provided with openings therethrough according to an embodiment;

FIG. 2b is a longitudinal cross sectional view of the substrate of FIG. 2a along lines B-B.

FIG. 3a is a view similar to FIG. 2a showing the openings as having been provided with respective seed conductive coatings therethrough according to an embodiment;

FIG. 3b is a longitudinal cross sectional view of the substrate of FIG. 3a along lines C-C.

FIG. 4a is a view similar to FIG. 3a showing the respective seed conductive coatings as having been separated into a plurality of seed conductive coating portions according to an embodiment;

FIG. 4b is a longitudinal cross sectional view of the substrate of FIG. 4a along lines D-D.

FIG. 5a is a view similar to FIG. 4a showing any seed conductive material residue to have been cleaned from gaps separating the seed conductive coating portions according to an embodiment;

FIG. 5b is a longitudinal cross sectional view of the substrate of FIG. 5a along lines E-E.

FIG. 6a is a view similar to FIG. 5a showing the seed conductive coating portions as having been provided with respective further conductive coatings according to an embodiment to provide corresponding connections;

FIG. 6b is a longitudinal cross sectional view of the substrate of FIG. 6a along lines F-F.

FIG. 7a is a view similar to FIG. 6a showing a PCB having PTH's with multiple connections;

FIG. 7b is a longitudinal cross sectional view of the substrate of FIG. 7a along lines G-G.

FIG. 8 is a schematic depiction of a system including the PCB of FIGS. 7a and 7b according to an embodiment.

### DETAILED DESCRIPTION

A method of fabricating a printed circuit board having a plated through hole with multiple connections, a printed circuit board fabricated according to the method, and a system including the printed circuit board are disclosed herein.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention; however, the order of description should not be construed as to imply that these operations are necessarily order dependent. In particular, these operations need not be performed in the order of presentation.

The phrase “one embodiment” is used repeatedly. The phrase generally does not refer to the same embodiment, however, it may. The terms “comprising”, “having” and “including” are synonymous, unless the context dictates otherwise.

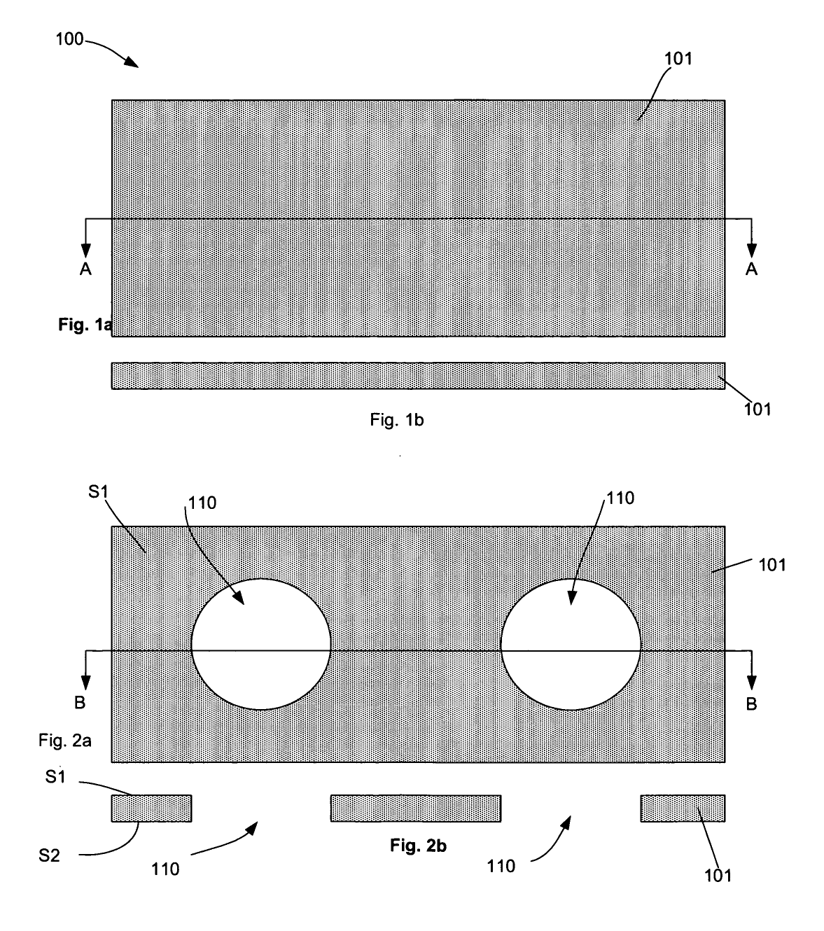

Referring now to FIGS. 1a and 1b by way of example, embodiments of the present invention comprise providing a microelectronic substrate or core layer, such as substrate 100, provided on a conductive layer 101. The substrate may include a non-conductive material, such as plastic or fiberglass, such as ABF, or any other dielectric suitable to serve as a substrate for a printed circuit board.

As seen in FIGS. 2a and 2b by way of example, embodiments of the present invention comprise providing a PTH opening, such as openings 110, in the substrate, such as substrate 100. As seen in FIG. 2b, openings 110 may be provided to extend from one surface S1 of substrate 100 to another, opposing surface S2 of the substrate 100. According to a preferred embodiment, the opening, such as openings 110, may be provided according to any one of well known methods as would be readily recognizable by one skilled in the art, such as, for example, using either mechanical or laser drilling.

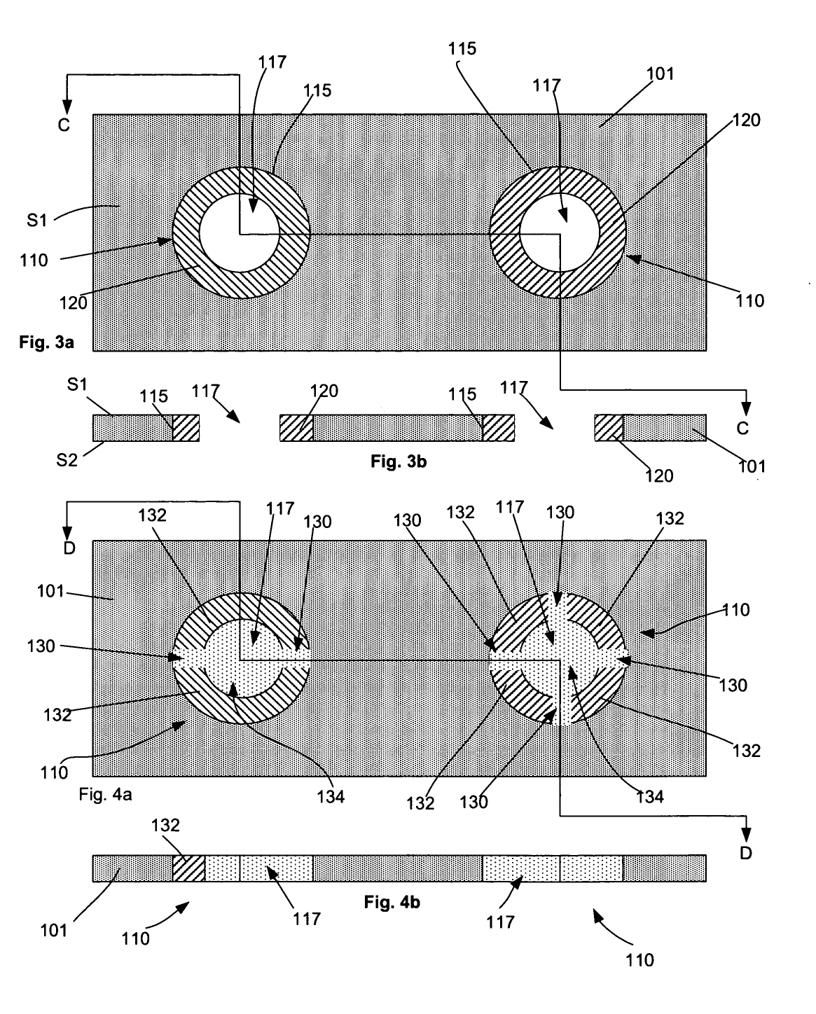

As next seen in FIGS. 3a and 3b by way of example, embodiments of the present invention comprise metallizing the walls of the opening to provide a conductive coating thereon. By “conductive coating,” what is meant in the context of the instant description is a conformal conductive layer that coats a given surface. In the case of a “coating” provided on walls of an opening, the “coating” as used herein would define a hollow region at a central region of the opening. Thus, by way of example, as seen in FIGS. 3a and 3b, metallizing could, according to an embodiment, comprise metallizing walls 115 of openings 110 to provide a seed conductive coating, such as seed conductive coating 120, within each one of the openings. As seen in FIG. 3b, the seed conductive coating 120 adheres to walls 115 of a corresponding opening 110 and provides a conformal conductive layer that extends across a length of the opening from one surface S1 of the substrate to an opposing surface S2 of the substrate, and that further defines a hollow region 117 at a central region of opening 110. Metallization of the openings according to one embodiment may comprise electrolessly plating the openings, such as openings 110, to obtain seed conductive coating 120. According to one embodiment, seed conductive coating 120 may comprise, by way of example, a coating of electrolessly deposited copper.

As next seen in FIGS. 4a and 4b by way of example, embodiments of the present invention comprise providing gaps in the conductive coating, such as in the seed conductive coating described above, to yield a plurality of conductive coating portions. By “gap,” what is meant in the context of the instant invention is any discontinuity provided in the conductive coating that extends through an entire thickness of the conductive coating and along an entire length of the conductive coating, that is, from one surface of the substrate to another, opposing surface of the substrate, to separate adjacent ones of the resulting conductive coating portions from one another. As seen in FIGS. 4a and 4b, an embodiment comprises providing gaps 130 in the seed conductive coating 120 to provide discontinuities to define seed conductive coating portions 132 between respective pairs of gaps, adjacent ones of the portions 132 being separated by the gaps 130, and facing ones of the portions 132 being separated by the hollow region 117. Provision of the gaps according to embodiments may result in the generation of a conductive material residue, such as residue 134, from the conductive coating, as shown in FIGS. 4a and 4b, residue 134 existing in the gaps 130 and in the hollow region 117. The number of seed conductive coating portions corresponding to a given PTH determines the number of connections to be provided by the PTH according to embodiments. By “connection,” what is meant in the context of embodiments is a conductive microstructure adapted to provide electrical connection between two respective sides of a substrate. According to embodiments, the seed conductive coating could be separated into as many seed conductive coating portions as feasible according to application needs by providing the corresponding number of gaps therein. Thus, as seen in opening 110 to the left of FIGS. 4a and 4b, two gaps 130 are provided to result in two seed conductive coating portions 132, while, as seen in openings 110 to the right of FIGS. 4a and 4b, four gaps 130 are provided to result in four seed conductive coating portions 132 as shown.

According to a preferred embodiment, providing gaps in the conductive coating comprises using selective laser irradiation of regions of the conductive coating that are to be provided with gaps in order to ablate those regions. Selective laser irradiation could be used to ablate gaps 130 into seed conductive coating 120. The types of lasers that may be used according to some embodiments may include a UV laser or a Nd-YAG laser. Laser parameters according to embodiments would be dependent on process parameters, as would be recognized by one skilled in the art. Embodiments are not limited to laser ablation, however, and would encompass any other method for providing gaps as described above, such as, for example, mechanical drilling.

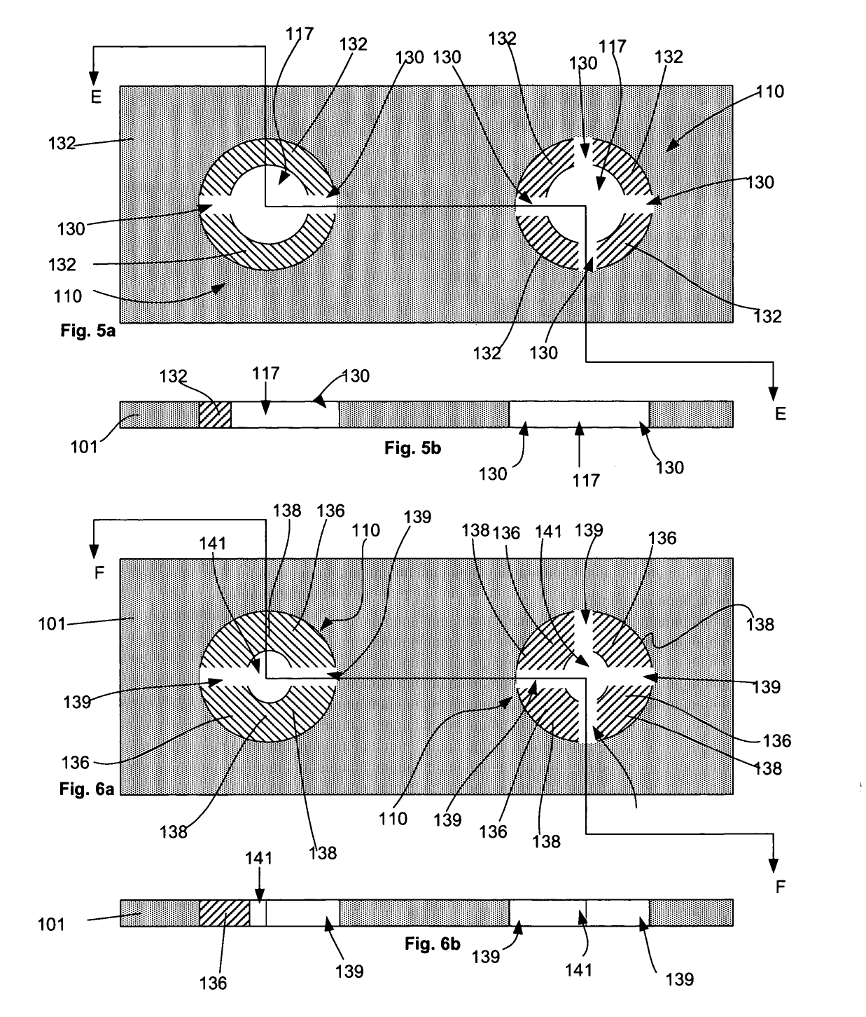

Referring next to FIGS. 5a and 5b by way of example, an embodiment comprises cleaning conductive material residue from spaces separating the conductive coating portions. “Spaces” as used herein consist of the gaps provided in the conductive coating, such as gaps 130, and, in addition, of the hollow region defined by the conductive coating, such as hollow region 117. Thus, as seen in FIGS. 5a and 5b, and also referring to FIGS. 4a and 4b, the noted embodiment may comprise, by way of example, cleaning conductive material residue 134 from spaces consisting of gaps 130 and of hollow region 117 to ensure electrical isolation between the conductive coating portions 132. Cleaning according to an embodiment may include using etching, such as, for example, a wet etch.

Referring next to FIGS. 6a and 6b by way of example, an embodiment of the present invention comprises electrolytically plating the seed conductive coating portions to provide respective connections through the opening. Thus, as seen in FIGS. 6a and 6b, an embodiment may comprise electrolytically plating the seed conductive coating portions 132 to provide respective connections 136 through each of the openings 110. In the embodiment of FIGS. 6a and 6b, the connections comprise an electrolytically plated layer 138. According to one embodiment, layer 138 may comprise copper. It is noted that FIGS. 6a and 6b do not show the seed conductive coating portions 132 shown in the previous figures since, as would be recognized by one skilled in the art, the seed conductive coating portions 132 would have served as sites of atomic nucleation for the electrolytically deposited layer 138 of each of the connections, the atoms in the seed conductive coating portions thus having been at least in part dispersed within layer 138 and not easily identifiable within a given location. It is noted that embodiments do not necessarily require the provision of both a seed conductive coating and of an electrolytically plated layer as described with respect to FIGS. 3a and 3b and 6a and 6b. Embodiments encompass within their scope the provision of a conductive coating on the walls of the openings through metallization that may include a single deposited layer (not shown) or any number of deposited layers as would be recognized by one skilled in the art. It is additionally noted that the connections according to embodiments, such as, for example, connections 136, are separated by separation regions. With respect to the separation regions, when the conductive coating comprises a single deposited layer of conductive material according to an embodiment, the separation regions for each PTH would correspond to a combination of the gaps and hollow region separating the conductive coating portions as described above. In the case of the shown embodiment, the separation regions correspond to extended gaps 139 and to a reduced hollow region 141, the gaps 130 (FIGS. 5a and 5b) having been extended as a result of electrolytic plating of the seed conductive coating portions 132 to result in extended gaps 139, and the hollow region 117 (FIGS. 5a and 5b) having been reduced in size for the same reason to result in reduced hollow region 141.

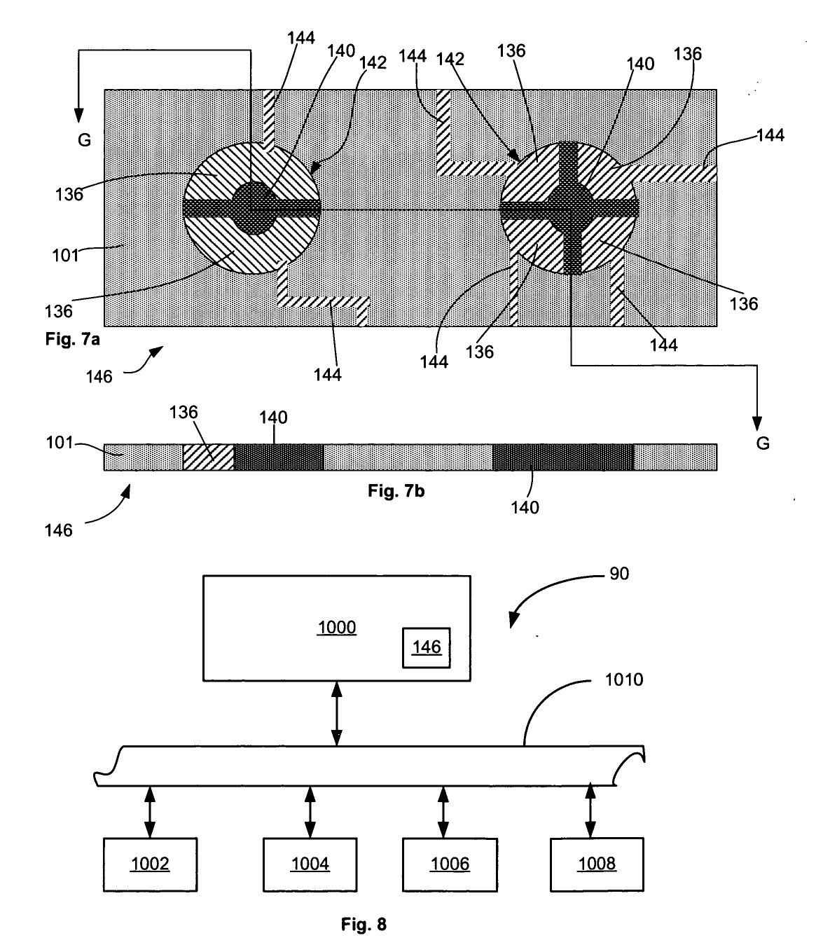

Referring next to FIGS. 7a and 7b by way of example, embodiments comprise providing an electrically insulating material in separations regions between the connections to provide a substrate having a PTH including multiple connections. Thus, an electrically insulating material 140 may be provided in separations regions of each of the openings 110, for example by a printing process, to provide respective PTH's 142, each of which comprises multiple connections 136. The electrically insulating material according to embodiments may comprise any of the well known plugging materials

Referring again to FIGS. 7a and 7b by way of example, embodiments comprise providing circuitizing the substrate to provide electrical connections to and from each of the connections of the PTH to yield a printed circuit board. Thus, circuitizing according to one embodiment may comprise providing conductive traces 144 (shown on only one side of the substrate) on substrate 100 to provide electrical connections to and from each of the connections 136 of the PTH's 142 to yield printed circuit board 146 as shown. Circuitizing according to embodiments may involve any of the well know circuitization methods for providing conductive traces, as would be within the knowledge of one skilled in the art.

Advantageously, embodiments of the present invention provide a reliable and cost-effective method for increasing the number of through connections on a PCB without the need for a closer spacing of PTH's or for reduced diameter PTH's. Accordingly, embodiments advantageously allow the provision of an increased number of connections on a PCB while reducing the flip chip substrate form factor. Embodiments are even more desirable for future generation flip chip substrates requiring a higher input/output count.

Referring to FIG. 8, there is illustrated one of many possible systems in which embodiments of the present invention may be used. The shown system 90 therefore comprises an electronic assembly 1000 which includes a printed circuit board such as, for example, printed circuit board 146 of FIGS. 8a and 8b described above. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 9, the system 90 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 106 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method of fabricating a printed circuit board comprising:
providing a substrate;
providing a through hole opening in the substrate;
metallizing walls of the opening to provide a conductive coating thereon defining a hollow region within the opening;
providing gaps in the conductive coating to yield a corresponding number of conductive coating portions separated by the gaps and by the hollow region;
filling the gaps and the hollow region with an electrically insulating material to electrically isolate the conductive coating portions from one another to provide a plated through hole including a plurality of connections; wherein each of the conductive coating portions defines at least part of a connection of the plurality of connections;
circuitizing the substrate to provide conductive traces thereon connected to corresponding ones of the plurality of connections to yield the printed circuit board.

2. The method of claim 1, wherein providing a through hole opening comprises one of laser and mechanical drilling the opening.

3. The method of claim 1, wherein:
the conductive coating comprises a seed conductive coating and the conductive coating portions comprise seed conductive coating portions;
the method further comprising electrolytically plating the seed conductive coating portions to provide respective ones of the plurality of connections of the plated through hole, electrolytically plating further extending the gaps to provide extended gaps and reducing the hollow region to provide a reduced hollow region; and
filling the gaps and the hollow region comprises filling the extended gaps and the reduced hollow region with an electrically insulating material to electrically isolate respective ones of the connections from one another to provide the plated through hole.

4. The method of claim 1, wherein metallizing comprises electrolessly plating walls of the opening.

5. The method of claim 1, wherein providing gaps comprises using selective laser irradiation of regions of the conductive coating to be provided with gaps to ablate those regions to yield the gaps.

6. The method of claim 5, wherein selective laser irradiation comprises using one of a UV laser and a Nd-YAG laser.

7. The method of claim 1, further comprising cleaning any conductive material residue from spaces separating the conductive coating portions.

8. The method of claim 7, wherein cleaning comprises etching.

9. The method of claim 8, wherein etching comprises wet etching.

10. The method of claim 8, wherein the connections comprise copper.

11. A printed circuit board comprising:
a substrate defining a through hole opening therein;
a plurality of connections disposed within the opening and adhered to the walls of the opening, the connections defining separation regions therebetween;
an electrically insulating material disposed in the separation regions to electrically isolate the connections from one another; and
conductive traces connected to corresponding ones of the connections.

12. The printed circuit board of claim 11, wherein the separation regions include gaps between adjacent connections and a hollow region between facing ones of the connections.

13. The printed circuit board of claim 11, wherein the connections comprise copper.

14. The printed circuit board of claim 11, wherein the electrically insulating material comprises a plugging material.

15. A substrate comprising:
a plurality of connections disposed within a through hole opening defined in the substrate, the connections being adhered to the walls of the opening and further defining separation regions therebetween;
an electrically insulating material disposed in the separation regions to electrically isolate the connections from one another.

16. The substrate of claim 15, wherein the separation regions include gaps between adjacent connections and a hollow region between facing ones of the connections.

17. The substrate of claim 15, wherein the connections comprise copper.

18. The substrate of claim 15, wherein the electrically insulating material comprises a plugging material.

19. A system comprising:
a microelectronic assembly including:
a printed circuit board comprising:
a substrate defining a through hole opening therein;
a plurality of connections disposed within the opening and adhered to the walls of the opening, the connections defining separation regions therebetween;
an electrically insulating material disposed in the separation regions to electrically isolate the connections from one another; and
conductive traces connected to corresponding ones of the connections; and
a main memory coupled to the microelectronic assembly.

20. The system of claim 19, wherein the separation regions include gaps between adjacent connections and a hollow region between facing ones of the connections.

21. The system of claim 19, wherein the connections comprise copper.

22. The system of claim 19, wherein the electrically insulating material comprises a plugging material.
